(19) United States
(12) Patent Application Publication
(10) Pub. No.: US 2025/0087626 A1
(43) Pub. Date: Mar. 13, 2025

(54) CHIP TRANSFERRING AND BONDING DEVICE, AND CHIP TRANSFERRING AND BONDING METHOD

(71) Applicant: ASTI GLOBAL INC., TAIWAN, Taichung City (TW)

(72) Inventor: CHIEN-SHOU LIAO, Taichung City (TW)

(21) Appl. No.: 18/777,493

(22) Filed: Jul. 18, 2024

Related U.S. Application Data
(60) Provisional application No. 63/537,472, filed on Sep. 8, 2023.

(51) Int. Cl. H01L 23/00

(52) U.S. Cl. CPC H01L 24/75; H01L 24/81; H01L 2224/75262; H01L 2224/75263; H01L 2224/81048; H01L 2224/81097; H01L 2224/81224; H01L 2224/81801; H01L 2924/401

(57) ABSTRACT

A chip transferring and bonding device, and a chip transferring and bonding method are provided. The chip transferring and bonding device includes a signal control module, a substrate carrying module, a chip transferring module, a substrate preheating module and a chip bonding module. The substrate preheating module is configured to preheat the circuit substrate at a predetermined preheating temperature, thereby allowing the soldering materials disposed between each chip and the circuit substrate to be preheated at the predetermined preheating temperature. The chip bonding module is configured to instantaneously heat the soldering materials disposed between each chip and the circuit substrate at a predetermined heating temperature. When the substrate preheating module and the chip bonding module are optionally configured to be used simultaneously, the substrate preheating module is configured to provide a predetermined preheating temperature, and the chip bonding module is configured to provide a predetermined heating temperature.

### CROSS-REFERENCE TO RELATED PATENT APPLICATION

This application claims the benefit of priority to the U.S. Provisional Patent Application Ser. No. 63/537,472, filed on Sep. 8, 2023, which application is incorporated herein by reference in its entirety.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a transferring and bonding device, and a transferring and bonding method, and more particularly to a chip transferring and bonding device, and a chip transferring and bonding method.

### BACKGROUND OF THE DISCLOSURE

In the related art, semiconductor chips are bonded to the circuit board by heating in a solder machine. However, there is still room for improvement in the prior chip bonding device and the prior chip bonding method.

### SUMMARY OF THE DISCLOSURE

In response to the above-referenced technical inadequacy, the present disclosure provides a chip transferring and bonding device and a chip transferring and bonding method.

In order to solve the above-mentioned problems, one of the technical aspects adopted by the present disclosure is to provide a chip transferring and bonding device, which includes a signal control module, a substrate carrying module, a chip transferring module, a substrate preheating module and a chip bonding module. The substrate carrying module is electrically connected to the signal control module. The chip transferring module is electrically connected to the signal control module and movably disposed above the substrate carrying module. The substrate preheating module is electrically connected to the signal control module and configured to correspond to the substrate carrying module. The chip bonding module is electrically connected to the signal control module and configured to correspond to the substrate carrying module. When the substrate carrying module is optionally configured to be used, the substrate carrying module is allowed to be configured through the signal control module to carry a circuit substrate. When the chip transferring module is optionally configured to be used, the chip transferring module is allowed to be configured through the signal control module to transfer a plurality of chips to the circuit substrate. When the substrate preheating module is optionally configured to be used, the substrate preheating module is allowed to be configured through the signal control module to preheat the circuit substrate at a predetermined preheating temperature, thereby allowing a plurality of soldering materials disposed between each of the chips and the circuit substrate to be preheated at the predetermined preheating temperature that is provided by the substrate preheating module. When the chip bonding module is optionally configured to be used, the chip bonding module is allowed to be configured through the signal control module to instantaneously heat the soldering materials disposed between each of the chips and the circuit substrate at a predetermined heating temperature. When the substrate preheating module and the chip bonding module are optionally configured to be used simultaneously, the substrate preheating module is configured to provide the predetermined preheating temperature, and the chip bonding module is configured to provide the predetermined heating temperature.

In order to solve the above-mentioned problems, another one of the technical aspects adopted by the present disclosure is to provide a chip transferring and bonding device, which includes a signal control module, a substrate carrying module, a chip transferring module, a substrate preheating module and a chip bonding module. The chip transferring module is electrically connected to the signal control module and movably disposed above the substrate carrying module. The substrate preheating module is electrically connected to the signal control module. The chip bonding module is electrically connected to the signal control module. When the substrate preheating module and the chip bonding module are optionally configured to be used simultaneously, the substrate preheating module is configured to provide a predetermined preheating temperature, and the chip bonding module is configured to provide a predetermined heating temperature.

In order to solve the above-mentioned problems, yet another one of the technical aspects adopted by the present disclosure is to provide a chip transferring and bonding method, which includes: carrying a circuit substrate by a substrate carrying module; transferring a plurality of chips to the circuit substrate by a chip transferring module; preheating the circuit substrate at a predetermined preheating temperature by a substrate preheating module, thereby allowing a plurality of soldering materials disposed between each of the chips and the circuit substrate to be preheated at the predetermined preheating temperature that is provided by the substrate preheating module; and during the step of preheating the circuit substrate at the predetermined preheating temperature by the substrate preheating module, instantaneously heating the soldering materials disposed between each of the chips and the circuit substrate at a predetermined heating temperature by a chip bonding module. When the substrate preheating module and the chip bonding module are optionally configured to be used simultaneously, the substrate preheating module is configured to provide the predetermined preheating temperature, and the chip bonding module is configured to provide the predetermined heating temperature.

Therefore, in the chip transferring and bonding device provided by the present disclosure, by virtue of “the substrate preheating module being configured to provide a predetermined preheating temperature” and “the chip bonding module being configured to provide a predetermined heating temperature,” when the substrate preheating module and the chip bonding module are optionally configured to be used simultaneously, the circuit substrate and the soldering materials can be instantaneously and directly heated from the predetermined preheating temperature to the predetermined heating temperature.

Furthermore, in the chip transferring and bonding method provided by the present disclosure, by virtue of “carrying a circuit substrate by a substrate carrying module,” “transferring a plurality of chips to the circuit substrate by a chip transferring module,” “preheating the circuit substrate at a predetermined preheating temperature by a substrate preheating module, thereby allowing a plurality of soldering materials disposed between each of the chips and the circuit substrate to be preheated at the predetermined preheating temperature that is provided by the substrate preheating module” and “during the step of preheating the circuit substrate at the predetermined preheating temperature by the substrate preheating module, instantaneously heating the soldering materials disposed between each of the chips and the circuit substrate at a predetermined heating temperature by a chip bonding module,” when the substrate preheating module and the chip bonding module are optionally configured to be used simultaneously, the circuit substrate and the soldering materials can be instantaneously and directly heated from the predetermined preheating temperature to the predetermined heating temperature.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a functional block diagram of a chip transferring and bonding device provided by the present disclosure;

FIG. 2 is a schematic view of step S100 and step S102 of a chip transferring and bonding method according to a first embodiment of the present disclosure;

FIG. 3 is a schematic view of step S104 of the chip transferring and bonding method according to the first embodiment of the present disclosure;

FIG. 4 is a schematic view of step S106 of the chip transferring and bonding method according to the first embodiment of the present disclosure (a schematic view in which a heating plate structure and a laser heater are optionally configured to be used simultaneously);

FIG. 5 is a schematic view of step S108 of the chip transferring and bonding method according to the first embodiment of the present disclosure;

FIG. 6 is a schematic view of step S110 of the chip transferring and bonding method according to the first embodiment of the present disclosure;

FIG. 7 is a flowchart of the chip transferring and bonding method according to the first embodiment of the present disclosure;

FIG. 8 is a schematic view of the chip transferring and bonding device provided by a second embodiment of the present disclosure (a schematic view in which a laser preheater and the laser heater are optionally configured to be used simultaneously);

FIG. 9 is a schematic view of the chip transferring and bonding device provided by a third embodiment of the present disclosure (a schematic view in which the heating plate structure and a plurality of micro heaters are optionally configured to be used simultaneously); and

FIG. 10 is a schematic view of the chip transferring and bonding device provided by a fourth embodiment of the present disclosure (a schematic view in which the laser preheater and the micro heaters are optionally configured to be used simultaneously).

### DETAILED DESCRIPTION OF THE EXEMPLARY EMBODIMENTS

The present disclosure is more particularly described in the following embodiments and examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

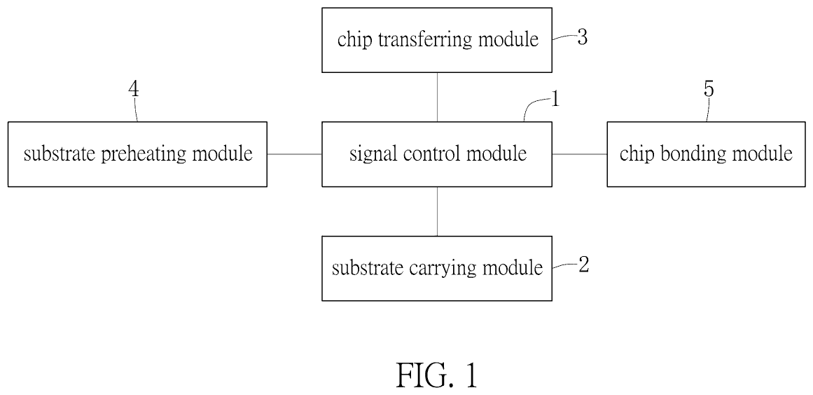

Referring to FIG. 1 to FIG. 10, the present disclosure provides a chip transferring and bonding device D, which at least includes a signal control module 1, a substrate carrying module 2, a chip transferring module 3, a substrate preheating module 4 and a chip bonding module 5. More particularly, the chip transferring module 3 can be electrically connected to the signal control module 1 and movably disposed above the substrate carrying module 2, the substrate preheating module 4 is electrically connected to the signal control module 1, and the chip bonding module 5 is electrically connected to the signal control module 1. It should be noted that when the substrate preheating module 4 and the chip bonding module 5 are optionally (or selectively) configured to be used simultaneously, the substrate preheating module 4 can be configured to directly or indirectly provide a predetermined preheating temperature to the soldering materials S, and the chip bonding module 5 can be configured to directly or indirectly provide a predetermined heating temperature to the soldering materials S. Therefore, when the substrate preheating module 4 and the chip bonding module 5 are optionally configured to be used at the same time, the soldering materials S can be instantaneously (or instantly) and directly heated from the predetermined preheating temperature to the predetermined heating temperature, thereby reducing or avoiding residual stress (or thermal stress) in the soldering area.

### First Embodiment

Referring to FIG. 1 to FIG. 6, a first embodiment of the present disclosure provides a chip transferring and bonding device D, which includes a signal control module 1, a substrate carrying module 2, a chip transferring module 3, a substrate preheating module 4 and a chip bonding module 5.

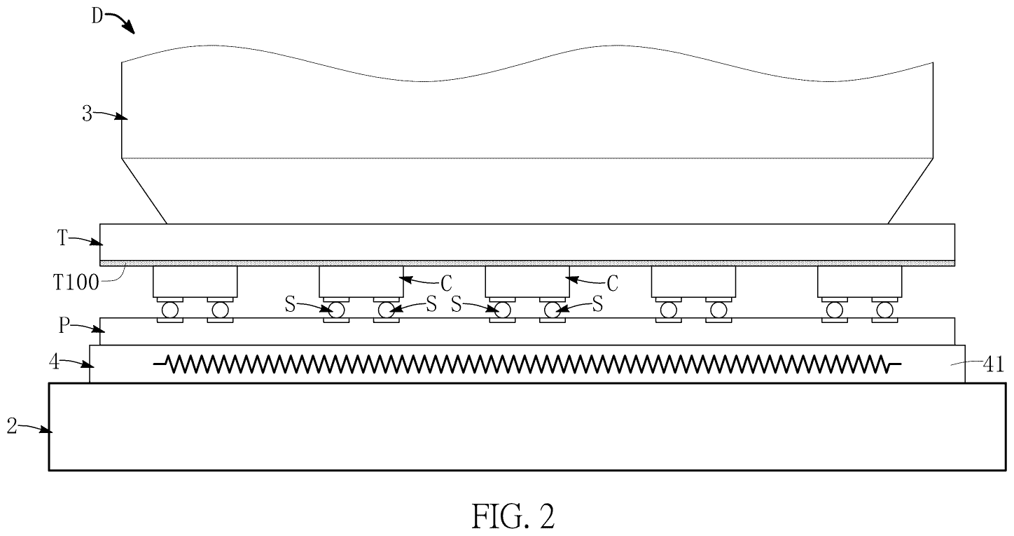

More particularly, referring to FIG. 1 and FIG. 2, the substrate carrying module 2 can be electrically connected to the signal control module 1, and the chip transferring module 3 can be electrically connected to the signal control module 1 and movably disposed above the substrate carrying module 2. For example, the signal control module 1 can be a desktop computer, a laptop computer, a tablet computer or any kind of portable electronic device that at least includes a central processing unit (CPU), a digital signal processor (DSP), a microprocessor (MPU), a microcontroller (MCU) or any kind of signal control chip. Moreover, the substrate carrying module 2 can be a movable clamp, a movable vacuum suction nozzle, or any kind of stage, which can be used to carry any kind of substrate. In addition, the chip transferring module 3 (or the chip moving module, or a chip carrying module) can be a movable clamping jaw, a movable vacuum nozzle, or any kind of chip transferring structure that can be used to transfer the chip from one place to another. It should be noted that when the substrate carrying module 2 is optionally configured to be used, the substrate carrying module 2 can be allowed to be configured through the signal control module 1 to carry a circuit substrate P (or the substrate carrying module 2 can indirectly carry the circuit substrate P through the substrate preheating module 4). In addition, when the chip transferring module 3 is optionally configured to be used, the chip transferring module 3 can be allowed to be configured through the signal control module 1 to transfer a plurality of chips C (such as LED chips or any kind of semiconductor chips, or dies, or electronic components) to the circuit substrate P. More particularly, the chip transferring module 3 can be configured to carry or move a temporary carrying substrate T (such as a glass substrate, a plastic substrate, or a light-transmitting substrate that can be made of any material), and the chips C can be pre-attached to an adhesive layer T100 of the temporary carrying substrate T. However, the aforementioned details are disclosed for exemplary purposes only, and are not meant to limit the scope of the present disclosure.

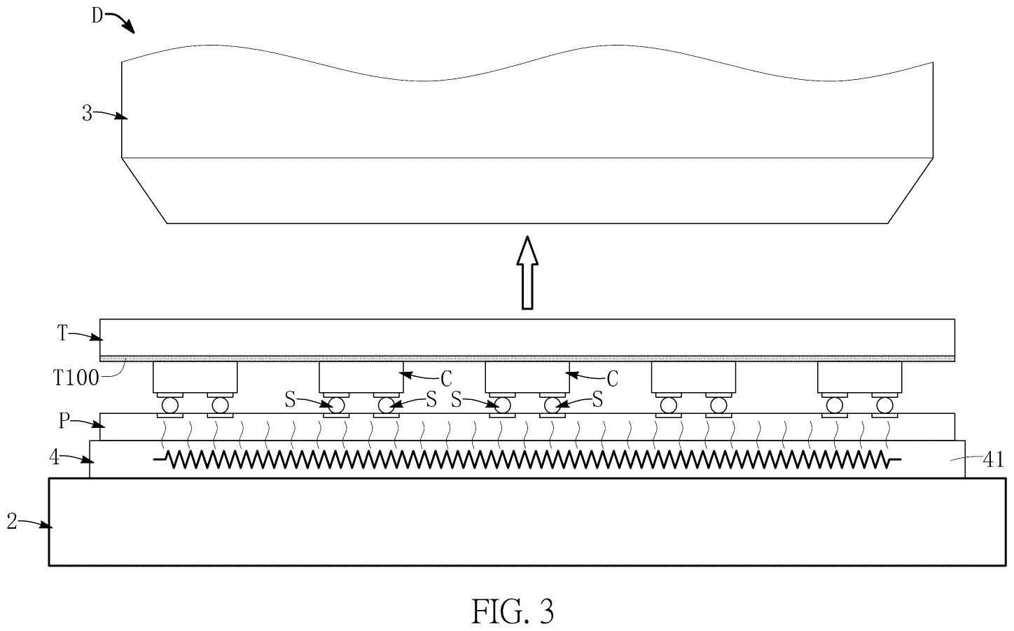

More particularly, referring to FIG. 1, FIG. 2 and FIG. 3, the substrate preheating module 4 is electrically connected to the signal control module 1 and configured to correspond to the substrate carrying module 2. For example, when the substrate preheating module 4 is optionally configured to be used, the substrate preheating module 4 can be allowed to be configured through the signal control module 1 to preheat the circuit substrate P at a predetermined preheating temperature (or by a specific preheating temperature), thereby allowing a plurality of soldering materials S that is disposed between each chip C and the circuit substrate P to be preheated at the predetermined preheating temperature that is provided by the substrate preheating module 4. In one of the feasible embodiments, the substrate preheating module 4 includes a heating plate structure 41 (such as a heating structure having at least one heating coil or at least one heater) for providing thermal energy, and the heating plate structure 41 of the substrate preheating module 4 is electrically connected to the signal control module 1 and disposed on the substrate carrying module 2. Therefore, when the heating plate structure 41 is optionally configured to be used, the heating plate structure 41 can be allowed to be configured through the signal control module 1 to transmit the thermal energy provided by the heating plate structure 41 to the soldering materials S that is disposed between each chip C and the circuit substrate P, thereby preheating the soldering materials S at the predetermined preheating temperature. That is to say, before the chip bonding module 5 is configured to instantaneously heat the soldering materials S that is disposed between each chip C and the circuit substrate P at the predetermined heating temperature (before proceeding with the heating step for the soldering materials S), the substrate preheating module 4 can be configured to preheat the circuit substrate P and the soldering materials S at the predetermined preheating temperature, so that the circuit substrate P and the soldering materials S can be gradually heated from a room temperature (such as 25° C.) to the predetermined preheating temperature (for example, the temperature of the soldering material S is raised from room temperature to a preheating temperature of any positive integer between 50° C. and 200° C., or a preheating temperature of any positive integer less than 50° C., or a preheating temperature of any positive integer greater than 200° C.). However, the aforementioned details are disclosed for exemplary purposes only, and are not meant to limit the scope of the present disclosure.

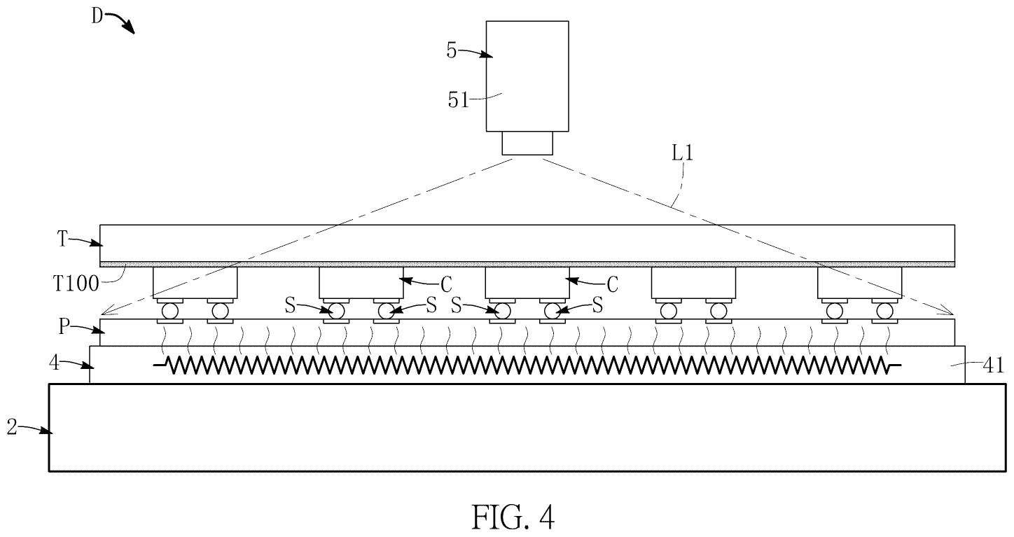

More particularly, referring to FIG. 1, FIG. 3 and FIG. 4, the chip bonding module 5 is electrically connected to the signal control module 1 and configured to correspond to the substrate carrying module 2. For example, when the chip bonding module 5 is optionally configured to be used, the chip bonding module 5 can be allowed to be configured through the signal control module 1 to instantaneously heat the soldering materials S that is disposed between each chip C and the circuit substrate P at a predetermined heating temperature (or a specific heating temperature). In one of the feasible embodiment, the chip bonding module 5 includes a laser heater 51 (such as a laser diode or any kind of laser generator configured for providing a luminescence wavelength or a luminescence band that can be adjusted or replaced according to different requirements) for providing a laser heating beam L1, and the laser heater 51 of the chip bonding module 5 is electrically connected to the signal control module 1 and movably or fixedly disposed above the substrate carrying module 2. Therefore, when the laser heater 51 is optionally configured to be used, the laser heater 51 can be allowed to be configured through the signal control module 1 to project the laser heating beam L1 generated by the laser heater 51 onto the soldering materials S that is disposed between each chip C and the circuit substrate P, thereby instantaneously heating the soldering materials S at the predetermined heating temperature. That is to say, when the chip bonding module 5 is configured to instantaneously heat the soldering materials S that is disposed between each chip C and the circuit substrate P at the predetermined heating temperature (during the heating step for the soldering materials S), the substrate preheating module 4 can be configured to continuously preheat the circuit substrate P and the soldering materials S at the predetermined preheating temperature, so that the circuit substrate P and the soldering materials S can be instantaneously heated from the predetermined preheating temperature to the predetermined heating temperature (for example, under the condition that the predetermined heating temperature is greater than the predetermined preheating temperature, the temperature of the soldering material S is raised from the predetermined preheating temperature to a heating temperature of any positive integer between 200° C. and 300° C., or a heating temperature of any positive integer less than 200° C., or a heating temperature of any positive integer greater than 200° C.). That is to say, during the heating step for the soldering materials S, the circuit substrate P and the soldering materials S will not be instantaneously heated directly from room temperature to the predetermined heating temperature, thereby avoiding residual thermal stress in the soldering area due to instantaneous thermal expansion and contraction. However, the aforementioned details are disclosed for exemplary purposes only, and are not meant to limit the scope of the present disclosure.

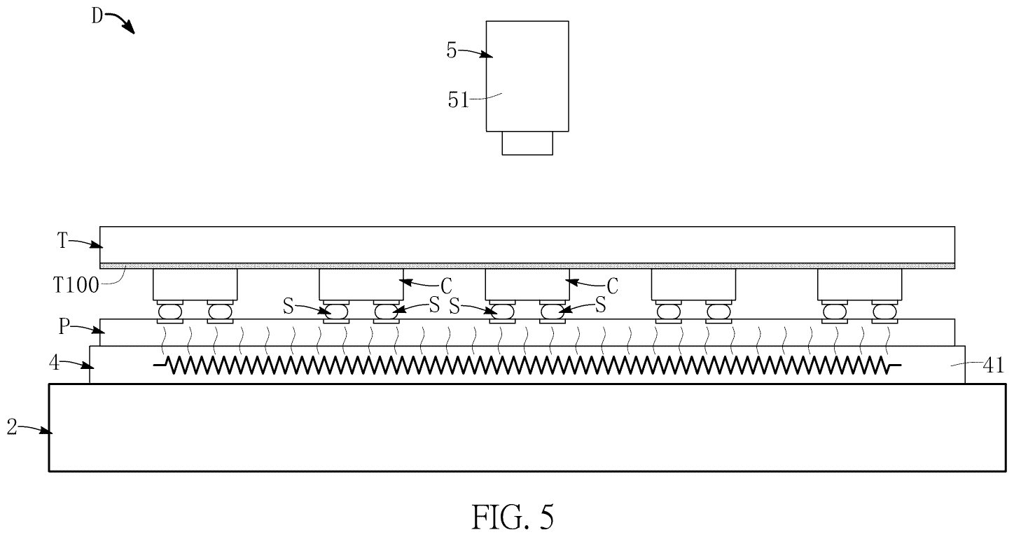

More particularly, referring to FIG. 1, FIG. 4 and FIG. 5, after the chip bonding module 5 is configured to instantaneously heat the soldering materials S that is disposed between each chip C and the circuit substrate P at the predetermined heating temperature (after completing the heating step for the soldering materials S), the substrate preheating module 4 can be configured to continuously preheat the circuit substrate P and the soldering materials S at the predetermined preheating temperature (so as to keep the temperature constant, or keep the temperature constant) to prevent the circuit substrate P and the soldering materials S from being instantaneously cooled down from the predetermined heating temperature to the room temperature (or to avoid residual thermal stress in the soldering area due to instantaneous thermal expansion and contraction), thereby increasing the connection strength or bonding strength between the soldering material S and the chip C, and increasing the connection strength or bonding strength between the soldering material S and the circuit board P.

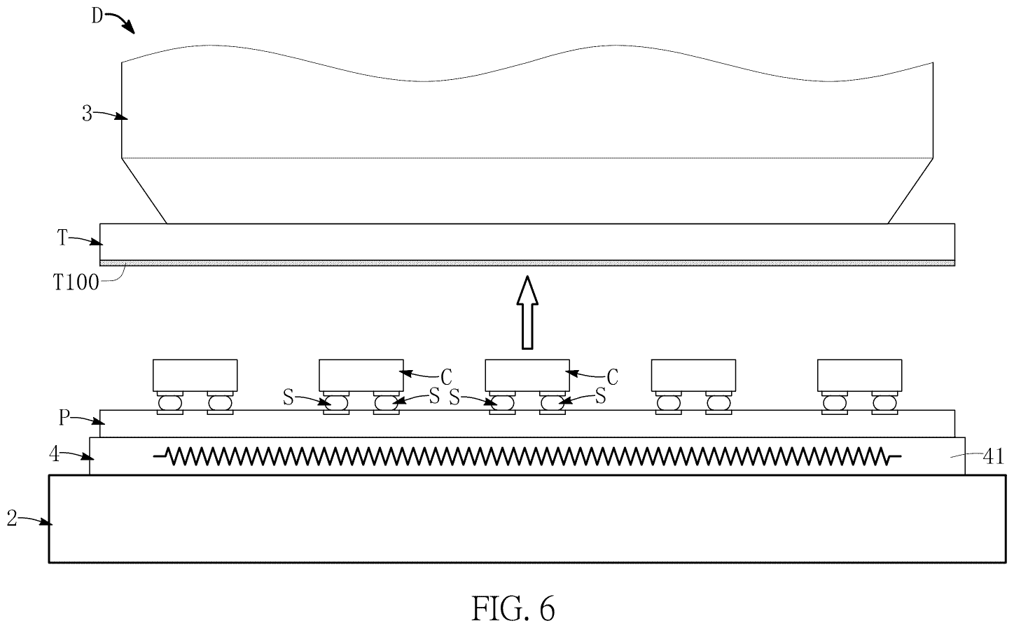

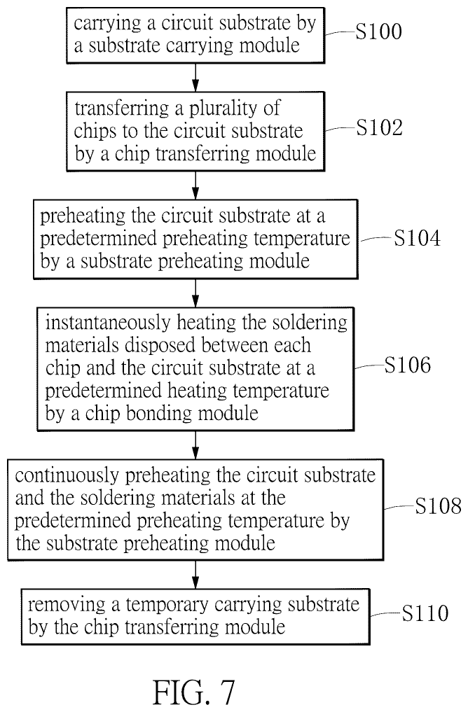

It should be noted that referring to FIG. 1 to FIG. 7, the first embodiment of the present disclosure further includes a chip transferring and bonding method, which includes: firstly, referring to FIG. 2 and FIG. 7, carrying a circuit substrate P by a substrate carrying module 2 (step S100), and then transferring a plurality of chips C to the circuit substrate P by a chip transferring module 3 (step S102); next, referring to FIG. 3 and FIG. 7, preheating the circuit substrate P at a predetermined preheating temperature by a substrate preheating module 4 (step S104), thereby allowing a plurality of soldering materials S that is disposed between each chip C and the circuit substrate P to be preheated at the predetermined preheating temperature that is provided by the substrate preheating module 4; then, referring to FIG. 4 and FIG. 7, during the step of preheating the circuit substrate P at the predetermined preheating temperature by the substrate preheating module 4 (that is to say, the circuit substrate P and the soldering materials S can be maintained in a constant temperature state), instantaneously heating the soldering materials S that is disposed between each chip C and the circuit substrate P at a predetermined heating temperature by a chip bonding module 5 (step S106); afterward, referring to FIG. 5 and FIG. 7, continuously preheating (or keep warm) the circuit substrate P and the plurality of soldering materials S at the predetermined preheating temperature (or continuously maintaining the temperature of the circuit substrate P and the soldering materials S at the predetermined preheating temperature) by the substrate preheating module 4 (step S108), so as to prevent the circuit substrate P and the soldering materials S from being instantaneously cooled down from the predetermined heating temperature to the room temperature (or to avoid residual thermal stress in the soldering area due to instantaneous thermal expansion and contraction); next, referring to FIG. 6 and FIG. 7, removing a temporary carrying substrate T by the chip transferring module 3 (step S110).

It should be noted that as shown in FIG. 3, before the step S106 of instantaneously heating the soldering materials S that is disposed between each chip C and the circuit substrate P at the predetermined heating temperature by the chip bonding module 5, the substrate preheating module 4 can be configured to preheat the circuit substrate P and the soldering materials S at the predetermined preheating temperature, so that the circuit substrate P and the soldering materials S can be gradually heated from a room temperature to the predetermined preheating temperature, thereby avoiding residual thermal stress in the soldering area due to instantaneous thermal expansion and contraction.

It should be noted that as shown in FIG. 4, in the step S106 of instantaneously heating the soldering materials S that is disposed between each chip C and the circuit substrate P at the predetermined heating temperature by the chip bonding module 5, the substrate preheating module 4 can be configured to continuously preheat the circuit substrate P and the soldering materials S at the predetermined preheating temperature, so that the circuit substrate P and the soldering materials S can be instantaneously heated from the predetermined preheating temperature to the predetermined heating temperature, thereby avoiding residual thermal stress in the soldering area due to instantaneous thermal expansion (or avoiding thermal stress in the soldering area between the soldering material S and the chip C, and in the soldering area between the soldering material S and the circuit substrate P).

It should be noted that as shown in FIG. 4 and FIG. 5, after the step S106 of instantaneously heating the soldering materials S that is disposed between each chip C and the circuit substrate P at the predetermined heating temperature by the chip bonding module 5, the substrate preheating module 4 can be configured to continuously preheat the circuit substrate P and the soldering materials S at the predetermined preheating temperature to prevent the circuit substrate P and the soldering materials S from being instantaneously cooled down from the predetermined heating temperature to the room temperature (or to avoid residual thermal stress in the soldering area due to instantaneous thermal contraction), thereby increasing the connection strength or bonding strength between the soldering material S and the chip C, and increasing the connection strength or bonding strength between the soldering material S and the circuit board P.

### Second Embodiment

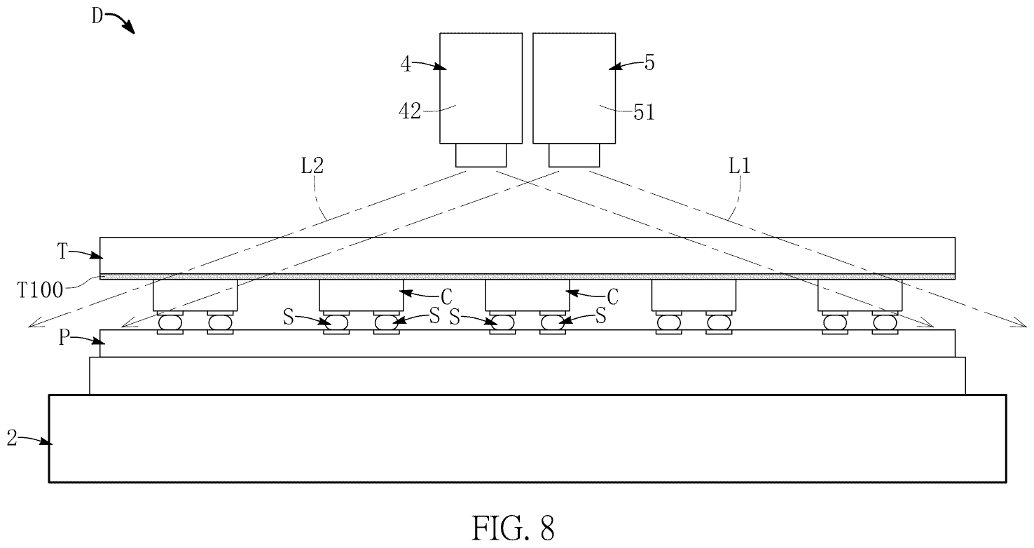

Referring to FIG. 1 and FIG. 8, a second embodiment of the present disclosure provides a chip transferring and bonding device D, which includes a signal control module 1, a substrate carrying module 2, a chip transferring module 3, a substrate preheating module 4 and a chip bonding module 5. Comparing FIG. 8 with FIG. 4, the main difference between the second embodiment and the first embodiment is as follows: in the second embodiment, the substrate preheating module 4 includes a laser preheater 42 (such as a laser diode or any kind of laser generator configured for providing a luminescence wavelength or a luminescence band that can be adjusted or replaced according to different requirements) for providing a laser preheating beam L2, and the laser preheater 42 of the substrate preheating module 4 is electrically connected to the signal control module 1 and movably or fixedly disposed above the substrate carrying module 2.

For example, as shown in FIG. 8, when the laser preheater 42 is optionally configured to be used, the laser preheater 42 can be allowed to be configured through the signal control module 1 to project the laser preheating beam L2 generated by the laser preheater 42 onto the soldering materials S that is disposed between each chip C and the circuit substrate P, thereby preheating the soldering materials S at the predetermined preheating temperature. It should be noted that when the chip bonding module 5 (or the laser heater 51) is configured to instantaneously heat the soldering materials S that is disposed between each chip C and the circuit substrate P at the predetermined heating temperature (during the heating step for the soldering materials S), the substrate preheating module 4 (or the laser preheater 42) can be configured to continuously preheat the circuit substrate P and the soldering materials S at the predetermined preheating temperature, so that the circuit substrate P and the soldering materials S can be instantaneously heated from the predetermined preheating temperature to the predetermined heating temperature (or the circuit substrate P and the soldering materials S will not be instantaneously heated directly from room temperature to the predetermined heating temperature), thereby avoiding residual thermal stress in the soldering area due to instantaneous thermal expansion.

### Third Embodiment

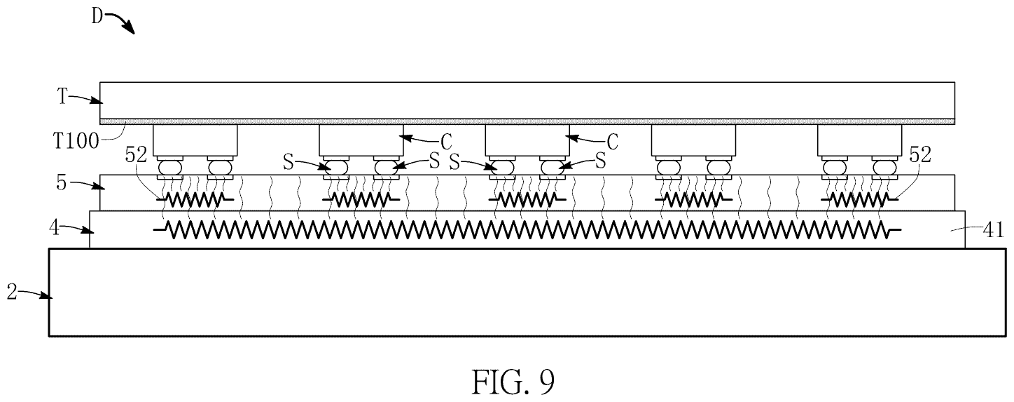

Referring to FIG. 1 and FIG. 9, a third embodiment of the present disclosure provides a chip transferring and bonding device D, which includes a signal control module 1, a substrate carrying module 2, a chip transferring module 3, a substrate preheating module 4 and a chip bonding module 5. Comparing FIG. 9 with FIG. 4, the main difference between the third embodiment and the first embodiment is as follows: in the third embodiment, the chip bonding module 5 includes a plurality of micro heaters 52 (such as metal wires, semiconductor chips or any kind of heating elements) for providing thermal energy, and the micro heaters 52 of the chip bonding module 5 are electrically connected to the signal control module 1 and disposed on (outside) or inside the circuit substrate P.

For example, as shown in FIG. 9, when the micro heaters 52 are optionally configured to be used, the micro heaters 52 can be allowed to be configured through the signal control module 1 to transmit the thermal energy provided by the micro heaters 52 to the soldering materials S that is disposed between each chip C and the circuit substrate P, thereby instantaneously heating the soldering materials S at the predetermined heating temperature. It should be noted that when the chip bonding module 5 (or the micro heaters 52) is configured to instantaneously heat the soldering materials S that is disposed between each chip C and the circuit substrate P at the predetermined heating temperature (during the heating step for the soldering materials S), the substrate preheating module 4 (or the heating plate structure 41) can be configured to continuously preheat the circuit substrate P and the soldering materials S at the predetermined preheating temperature, so that the circuit substrate P and the soldering materials S can be instantaneously heated from the predetermined preheating temperature to the predetermined heating temperature (or the circuit substrate P and the soldering materials S will not be instantaneously heated directly from room temperature to the predetermined heating temperature), thereby avoiding residual thermal stress in the soldering area due to instantaneous thermal expansion.

### Fourth Embodiment

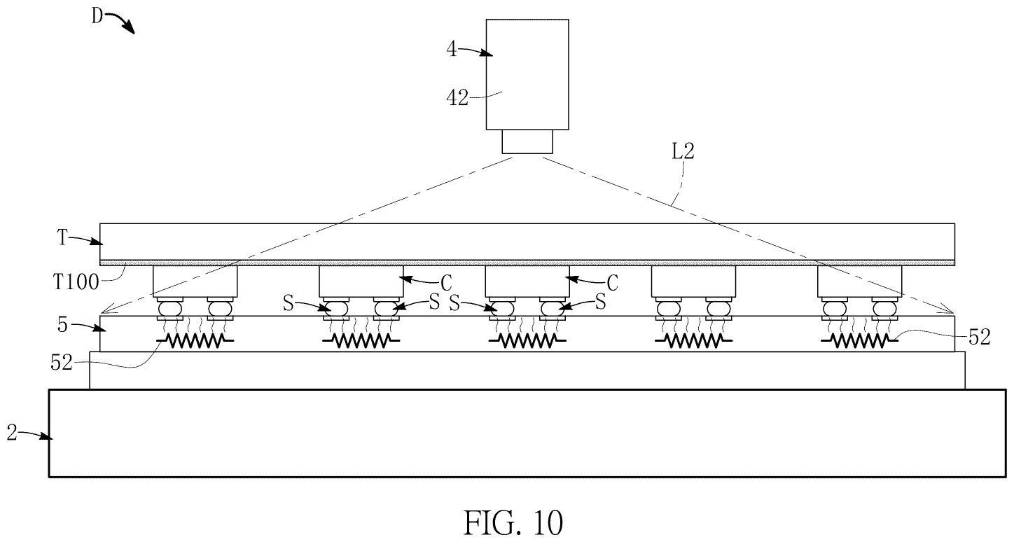

Referring to FIG. 1 and FIG. 10, a fourth embodiment of the present disclosure provides a chip transferring and bonding device D, which includes a signal control module 1, a substrate carrying module 2, a chip transferring module 3, a substrate preheating module 4 and a chip bonding module 5. Comparing FIG. 10 with FIG. 9, the main difference between the fourth embodiment and the third embodiment is as follows: in the fourth embodiment, the substrate preheating module 4 includes a laser preheater 42 (such as a laser diode or any kind of laser generator configured for providing a luminescence wavelength or a luminescence band that can be adjusted or replaced according to different requirements) for providing a laser preheating beam L2, and the laser preheater 42 of the substrate preheating module 4 is electrically connected to the signal control module 1 and movably or fixedly disposed above the substrate carrying module 2.

For example, as shown in FIG. 10, when the laser preheater 42 is optionally configured to be used, the laser preheater 42 can be allowed to be configured through the signal control module 1 to project the laser preheating beam L2 generated by the laser preheater 42 onto the soldering materials S that is disposed between each chip C and the circuit substrate P, thereby preheating the soldering materials S at the predetermined preheating temperature. It should be noted that when the chip bonding module 5 (or the micro heaters 52) is configured to instantaneously heat the soldering materials S that is disposed between each chip C and the circuit substrate P at the predetermined heating temperature (during the heating step for the soldering materials S), the substrate preheating module 4 (or the laser preheater 42) can be configured to continuously preheat the circuit substrate P and the soldering materials S at the predetermined preheating temperature, so that the circuit substrate P and the soldering materials S can be instantaneously heated from the predetermined preheating temperature to the predetermined heating temperature (or the circuit substrate P and the soldering materials S will not be instantaneously heated directly from room temperature to the predetermined heating temperature), thereby avoiding residual thermal stress in the soldering area due to instantaneous thermal expansion.

### Beneficial Effects of the Embodiments

In conclusion, in the chip transferring and bonding device D provided by the present disclosure, by virtue of “the substrate preheating module 4 being configured to provide a predetermined preheating temperature” and “the chip bonding module 5 being configured to provide a predetermined heating temperature,” when the substrate preheating module 4 and the chip bonding module 5 are optionally configured to be used simultaneously, the circuit substrate P and the soldering materials S can be instantaneously and directly heated from the predetermined preheating temperature to the predetermined heating temperature.

Furthermore, in the chip transferring and bonding method provided by the present disclosure, by virtue of “carrying a circuit substrate P by a substrate carrying module 2,” “transferring a plurality of chips C to the circuit substrate P by a chip transferring module 3,” “preheating the circuit substrate P at a predetermined preheating temperature by a substrate preheating module 4, thereby allowing a plurality of soldering materials S that is disposed between each chip C and the circuit substrate P to be preheated at the predetermined preheating temperature that is provided by the substrate preheating module 4” and “during the step of preheating the circuit substrate P at the predetermined preheating temperature by the substrate preheating module 4, instantaneously heating the soldering materials S that is disposed between each chip C and the circuit substrate P at a predetermined heating temperature by a chip bonding module 5,” when the substrate preheating module 4 and the chip bonding module 5 are optionally configured to be used simultaneously, the circuit substrate P and the soldering materials S can be instantaneously and directly heated from the predetermined preheating temperature to the predetermined heating temperature.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A chip transferring and bonding device, comprising:
a signal control module;
a substrate carrying module electrically connected to the signal control module;
a chip transferring module electrically connected to the signal control module and movably disposed above the substrate carrying module;
a substrate preheating module electrically connected to the signal control module and configured to correspond to the substrate carrying module; and
a chip bonding module electrically connected to the signal control module and configured to correspond to the substrate carrying module;
wherein, when the substrate carrying module is optionally configured to be used, the substrate carrying module is allowed to be configured through the signal control module to carry a circuit substrate;
wherein, when the chip transferring module is optionally configured to be used, the chip transferring module is allowed to be configured through the signal control module to transfer a plurality of chips to the circuit substrate;
wherein, when the substrate preheating module is optionally configured to be used, the substrate preheating module is allowed to be configured through the signal control module to preheat the circuit substrate at a predetermined preheating temperature, thereby allowing a plurality of soldering materials disposed between each of the chips and the circuit substrate to be preheated at the predetermined preheating temperature that is provided by the substrate preheating module;
wherein, when the chip bonding module is optionally configured to be used, the chip bonding module is allowed to be configured through the signal control module to instantaneously heat the soldering materials disposed between each of the chips and the circuit substrate at a predetermined heating temperature;
wherein, when the substrate preheating module and the chip bonding module are optionally configured to be used simultaneously, the substrate preheating module is configured to provide the predetermined preheating temperature, and the chip bonding module is configured to provide the predetermined heating temperature.

2. The chip transferring and bonding device according to claim 1,
wherein the substrate preheating module includes a heating plate structure for providing thermal energy, and the heating plate structure is electrically connected to the signal control module and disposed on the substrate carrying module;
wherein, when the heating plate structure is optionally configured to be used, the heating plate structure is allowed to be configured through the signal control module to transmit the thermal energy provided by the heating plate structure to the soldering materials disposed between each of the chips and the circuit substrate, thereby preheating the soldering materials at the predetermined preheating temperature;
wherein the chip bonding module includes a laser heater for providing a laser heating beam, and the laser heater is electrically connected to the signal control module and movably disposed above the substrate carrying module;
wherein, when the laser heater is optionally configured to be used, the laser heater is allowed to be configured through the signal control module to project the laser heating beam generated by the laser heater onto the soldering materials disposed between each of the chips and the circuit substrate, thereby instantaneously heating the soldering materials at the predetermined heating temperature;
wherein, before the chip bonding module is configured to instantaneously heat the soldering materials disposed between each of the chips and the circuit substrate at the predetermined heating temperature, the substrate preheating module is configured to preheat the circuit substrate and the soldering materials at the predetermined preheating temperature, so that the circuit substrate and the soldering materials are gradually heated from a room temperature to the predetermined preheating temperature;
wherein, when the chip bonding module is configured to instantaneously heat the soldering materials disposed between each of the chips and the circuit substrate at the predetermined heating temperature, the substrate preheating module is configured to continuously preheat the circuit substrate and the soldering materials at the predetermined preheating temperature, so that the circuit substrate and the soldering materials are instantaneously heated from the predetermined preheating temperature to the predetermined heating temperature;
wherein, after the chip bonding module is configured to instantaneously heat the soldering materials disposed between each of the chips and the circuit substrate at the predetermined heating temperature, the substrate preheating module is configured to continuously preheat the circuit substrate and the soldering materials at the predetermined preheating temperature to prevent the circuit substrate and the soldering materials from being instantaneously cooled down from the predetermined heating temperature to the room temperature.

3. The chip transferring and bonding device according to claim 1,
wherein the substrate preheating module includes a heating plate structure for providing thermal energy, and the heating plate structure is electrically connected to the signal control module and disposed on the substrate carrying module;
wherein, when the heating plate structure is optionally configured to be used, the heating plate structure is allowed to be configured through the signal control module to transmit the thermal energy provided by the heating plate structure to the soldering materials disposed between each of the chips and the circuit substrate, thereby preheating the soldering materials at the predetermined preheating temperature;
wherein the chip bonding module includes a plurality of micro heaters for providing thermal energy, and the micro heaters are electrically connected to the signal control module and disposed on or inside the circuit substrate;
wherein, when the micro heaters are optionally configured to be used, the micro heaters are allowed to be configured through the signal control module to transmit the thermal energy provided by the micro heaters to the soldering materials disposed between each of the chips and the circuit substrate, thereby instantaneously heating the soldering materials at the predetermined heating temperature;
wherein, before the chip bonding module is configured to instantaneously heat the soldering materials disposed between each of the chips and the circuit substrate at the predetermined heating temperature, the substrate preheating module is configured to preheat the circuit substrate and the soldering materials at the predetermined preheating temperature, so that the circuit substrate and the soldering materials are gradually heated from a room temperature to the predetermined preheating temperature;
wherein, when the chip bonding module is configured to instantaneously heat the soldering materials disposed between each of the chips and the circuit substrate at the predetermined heating temperature, the substrate preheating module is configured to continuously preheat the circuit substrate and the soldering materials at the predetermined preheating temperature, so that the circuit substrate and the soldering materials are instantaneously heated from the predetermined preheating temperature to the predetermined heating temperature;
wherein, after the chip bonding module is configured to instantaneously heat the soldering materials disposed between each of the chips and the circuit substrate at the predetermined heating temperature, the substrate preheating module is configured to continuously preheat the circuit substrate and the soldering materials at the predetermined preheating temperature to prevent the circuit substrate and the soldering materials from being instantaneously cooled down from the predetermined heating temperature to the room temperature.

4. The chip transferring and bonding device according to claim 1,
wherein, the substrate preheating module includes a laser preheater for providing a laser preheating beam, and the laser preheater is electrically connected to the signal control module and movably disposed above the substrate carrying module;
wherein, when the laser preheater is optionally configured to be used, the laser preheater is allowed to be configured through the signal control module to project the laser preheating beam generated by the laser preheater onto the soldering materials disposed between each of the chips and the circuit substrate, thereby preheating the soldering materials at the predetermined preheating temperature;
wherein the chip bonding module includes a laser heater for providing a laser heating beam, and the laser heater is electrically connected to the signal control module and movably disposed above the substrate carrying module;
wherein, when the laser heater is optionally configured to be used, the laser heater is allowed to be configured through the signal control module to project the laser heating beam generated by the laser heater onto the soldering materials disposed between each of the chips and the circuit substrate, thereby instantaneously heating the soldering materials at the predetermined heating temperature;
wherein, before the chip bonding module is configured to instantaneously heat the soldering materials disposed between each of the chips and the circuit substrate at the predetermined heating temperature, the substrate preheating module is configured to preheat the circuit substrate and the soldering materials at the predetermined preheating temperature, so that the circuit substrate and the soldering materials are gradually heated from a room temperature to the predetermined preheating temperature;
wherein, when the chip bonding module is configured to instantaneously heat the soldering materials disposed between each of the chips and the circuit substrate at the predetermined heating temperature, the substrate preheating module is configured to continuously preheat the circuit substrate and the soldering materials at the predetermined preheating temperature, so that the circuit substrate and the soldering materials are instantaneously heated from the predetermined preheating temperature to the predetermined heating temperature;
wherein, after the chip bonding module is configured to instantaneously heat the soldering materials disposed between each of the chips and the circuit substrate at the predetermined heating temperature, the substrate preheating module is configured to continuously preheat the circuit substrate and the soldering materials at the predetermined preheating temperature to prevent the circuit substrate and the soldering materials from being instantaneously cooled down from the predetermined heating temperature to the room temperature.

5. The chip transferring and bonding device according to claim 1,
wherein, the substrate preheating module includes a laser preheater for providing a laser preheating beam, and the laser preheater is electrically connected to the signal control module and movably disposed above the substrate carrying module;
wherein, when the laser preheater is optionally configured to be used, the laser preheater is allowed to be configured through the signal control module to project the laser preheating beam generated by the laser preheater onto the soldering materials disposed between each of the chips and the circuit substrate, thereby preheating the soldering materials at the predetermined preheating temperature;
wherein the chip bonding module includes a plurality of micro heaters for providing thermal energy, and the micro heaters are electrically connected to the signal control module and disposed on or inside the circuit substrate;
wherein, when the micro heaters are optionally configured to be used, the micro heaters are allowed to be configured through the signal control module to transmit the thermal energy provided by the micro heaters to the soldering materials disposed between each of the chips and the circuit substrate, thereby instantaneously heating the soldering materials at the predetermined heating temperature;
wherein, before the chip bonding module is configured to instantaneously heat the soldering materials disposed between each of the chips and the circuit substrate at the predetermined heating temperature, the substrate preheating module is configured to preheat the circuit substrate and the soldering materials at the predetermined preheating temperature, so that the circuit substrate and the soldering materials are gradually heated from a room temperature to the predetermined preheating temperature;
wherein, when the chip bonding module is configured to instantaneously heat the soldering materials disposed between each of the chips and the circuit substrate at the predetermined heating temperature, the substrate preheating module is configured to continuously preheat the circuit substrate and the soldering materials at the predetermined preheating temperature, so that the circuit substrate and the soldering materials are instantaneously heated from the predetermined preheating temperature to the predetermined heating temperature;
wherein, after the chip bonding module is configured to instantaneously heat the soldering materials disposed between each of the chips and the circuit substrate at the predetermined heating temperature, the substrate preheating module is configured to continuously preheat the circuit substrate and the soldering materials at the predetermined preheating temperature to prevent the circuit substrate and the soldering materials from being instantaneously cooled down from the predetermined heating temperature to the room temperature.

6. A chip transferring and bonding device, comprising:
a signal control module;
a substrate carrying module;
a chip transferring module electrically connected to the signal control module and movably disposed above the substrate carrying module;
a substrate preheating module electrically connected to the signal control module; and
a chip bonding module electrically connected to the signal control module;
wherein, when the substrate preheating module and the chip bonding module are optionally configured to be used simultaneously, the substrate preheating module is configured to provide a predetermined preheating temperature, and the chip bonding module is configured to provide a predetermined heating temperature.

7. The chip transferring and bonding device according to claim 6,
wherein the substrate carrying module is allowed to be configured through the signal control module to carry a circuit substrate;
wherein the chip transferring module is allowed to be configured through the signal control module to transfer a plurality of chips to the circuit substrate carrying a plurality of soldering materials;
wherein the substrate preheating module includes a heating plate structure for providing thermal energy, and the heating plate structure is electrically connected to the signal control module and disposed on the substrate carrying module;
wherein, when the heating plate structure is optionally configured to be used, the heating plate structure is allowed to be configured through the signal control module to transmit the thermal energy provided by the heating plate structure to the soldering materials disposed between each of the chips and the circuit substrate, thereby preheating the soldering materials at the predetermined preheating temperature;
wherein, the substrate preheating module includes a laser preheater for providing a laser preheating beam, and the laser preheater is electrically connected to the signal control module and movably disposed above the substrate carrying module;
wherein, when the laser preheater is optionally configured to be used, the laser preheater is allowed to be configured through the signal control module to project the laser preheating beam generated by the laser preheater onto the soldering materials disposed between each of the chips and the circuit substrate, thereby preheating the soldering materials at the predetermined preheating temperature;
wherein the chip bonding module includes a laser heater for providing a laser heating beam, and the laser heater is electrically connected to the signal control module and movably disposed above the substrate carrying module;
wherein, when the laser heater is optionally configured to be used, the laser heater is allowed to be configured through the signal control module to project the laser heating beam generated by the laser heater onto the soldering materials disposed between each of the chips and the circuit substrate, thereby instantaneously heating the soldering materials at the predetermined heating temperature;
wherein the chip bonding module includes a plurality of micro heaters for providing thermal energy, and the micro heaters are electrically connected to the signal control module and disposed on or inside the circuit substrate;
wherein, when the micro heaters are optionally configured to be used, the micro heaters are allowed to be configured through the signal control module to transmit the thermal energy provided by the micro heaters to the soldering materials disposed between each of the chips and the circuit substrate, thereby instantaneously heating the soldering materials at the predetermined heating temperature;
wherein, before the chip bonding module is configured to instantaneously heat the soldering materials disposed between each of the chips and the circuit substrate at the predetermined heating temperature, the substrate preheating module is configured to preheat the circuit substrate and the soldering materials at the predetermined preheating temperature, so that the circuit substrate and the soldering materials are gradually heated from a room temperature to the predetermined preheating temperature;
wherein, when the chip bonding module is configured to instantaneously heat the soldering materials disposed between each of the chips and the circuit substrate at the predetermined heating temperature, the substrate preheating module is configured to continuously preheat the circuit substrate and the soldering materials at the predetermined preheating temperature, so that the circuit substrate and the soldering materials are instantaneously heated from the predetermined preheating temperature to the predetermined heating temperature;
wherein, after the chip bonding module is configured to instantaneously heat the soldering materials disposed between each of the chips and the circuit substrate at the predetermined heating temperature, the substrate preheating module is configured to continuously preheat the circuit substrate and the soldering materials at the predetermined preheating temperature to prevent the circuit substrate and the soldering materials from being instantaneously cooled down from the predetermined heating temperature to the room temperature.

8. A chip transferring and bonding method, comprising:
carrying a circuit substrate by a substrate carrying module;
transferring a plurality of chips to the circuit substrate by a chip transferring module;
preheating the circuit substrate at a predetermined preheating temperature by a substrate preheating module, thereby allowing a plurality of soldering materials disposed between each of the chips and the circuit substrate to be preheated at the predetermined preheating temperature that is provided by the substrate preheating module; and
during the step of preheating the circuit substrate at the predetermined preheating temperature by the substrate preheating module, instantaneously heating the soldering materials disposed between each of the chips and the circuit substrate at a predetermined heating temperature by a chip bonding module;
wherein, when the substrate preheating module and the chip bonding module are optionally configured to be used simultaneously, the substrate preheating module is configured to provide the predetermined preheating temperature, and the chip bonding module is configured to provide the predetermined heating temperature.

9. The chip transferring and bonding method according to claim 8,
wherein the chip transferring module, the substrate preheating module and the chip bonding module are electrically connected to a signal control module;
wherein the substrate preheating module includes a heating plate structure for providing thermal energy, and the heating plate structure is electrically connected to the signal control module and disposed on the substrate carrying module;
wherein, when the heating plate structure is optionally configured to be used, the heating plate structure is allowed to be configured through the signal control module to transmit the thermal energy provided by the heating plate structure to the soldering materials disposed between each of the chips and the circuit substrate, thereby preheating the soldering materials at the predetermined preheating temperature;
wherein, the substrate preheating module includes a laser preheater for providing a laser preheating beam, and the laser preheater is electrically connected to the signal control module and movably disposed above the substrate carrying module;
wherein, when the laser preheater is optionally configured to be used, the laser preheater is allowed to be configured through the signal control module to project the laser preheating beam generated by the laser preheater onto the soldering materials disposed between each of the chips and the circuit substrate, thereby preheating the soldering materials at the predetermined preheating temperature;
wherein the chip bonding module includes a laser heater for providing a laser heating beam, and the laser heater is electrically connected to the signal control module and movably disposed above the substrate carrying module;
wherein, when the laser heater is optionally configured to be used, the laser heater is allowed to be configured through the signal control module to project the laser heating beam generated by the laser heater onto the soldering materials disposed between each of the chips and the circuit substrate, thereby instantaneously heating the soldering materials at the predetermined heating temperature;
wherein the chip bonding module includes a plurality of micro heaters for providing thermal energy, and the micro heaters are electrically connected to the signal control module and disposed on or inside the circuit substrate;
wherein, when the micro heaters are optionally configured to be used, the micro heaters are allowed to be configured through the signal control module to transmit the thermal energy provided by the micro heaters to the soldering materials disposed between each of the chips and the circuit substrate, thereby instantaneously heating the soldering materials at the predetermined heating temperature.

10. The chip transferring and bonding method according to claim 8,
wherein, before the chip bonding module is configured to instantaneously heat the soldering materials disposed between each of the chips and the circuit substrate at the predetermined heating temperature, the substrate preheating module is configured to preheat the circuit substrate and the soldering materials at the predetermined preheating temperature, so that the circuit substrate and the soldering materials are gradually heated from a room temperature to the predetermined preheating temperature;
wherein, when the chip bonding module is configured to instantaneously heat the soldering materials disposed between each of the chips and the circuit substrate at the predetermined heating temperature, the substrate preheating module is configured to continuously preheat the circuit substrate and the soldering materials at the predetermined preheating temperature, so that the circuit substrate and the soldering materials are instantaneously heated from the predetermined preheating temperature to the predetermined heating temperature;
wherein, after the chip bonding module is configured to instantaneously heat the soldering materials disposed between each of the chips and the circuit substrate at the predetermined heating temperature, the substrate preheating module is configured to continuously preheat the circuit substrate and the soldering materials at the predetermined preheating temperature to prevent the circuit substrate and the soldering materials from being instantaneously cooled down from the predetermined heating temperature to the room temperature.
